(19) United States
(12) Patent Application Publication
(10) Pub. No.: US 2010/0307567 A1
(43) Pub. Date: Dec. 9, 2010

(54) VARIANT PACKAGING STRUCTURE FOR A SOLAR MODULE

(76) Inventor: Min-Hsun HUANG, Mingjian Township (TW)

Correspondence Address: SINORICA, LLC, 2275 Research Blvd., Suite 500, ROCKVILLE, MD, 20850, US

(21) Appl. No.: 12/478,874

(22) Filed: Jun. 5, 2009

(51) Int. Cl. H01L 31/048

(52) U.S. Cl. 136/251

(57) ABSTRACT

A variant packaging structure for a solar module in the present invention includes a solar module that is shaped as a non-regular square and has an outer side sealed with a packaging layer. In addition to having function of converting solar energy into electric energy, the solar module of this invention can be made into various shapes for increasing decorative effect.

### BACKGROUND OF THE INVENTION

1. Field of the Invention

This invention relates to a variant packaging structure for a solar module.

2. Description of the Prior Art

Generally, a conventional solar panel 1 is square-shaped in an external appearance and has one side surface provided with two main welded wires 2 and lots of connection welded wires 3, as shown in FIG. 1. The main welded wires 2 are disposed on the surface of the solar panel 1, spaced apart and arranged in parallel, while the connection welded wires 3 are disposed at the opposite sides of the main welded wires 2, spaced apart and perpendicular to the main welded wires 2.

In spite of being able to convert solar energy into electric energy, the conventional solar panel 1 is quite monotonous and unvarying in an external appearance and hence it is usually installed on the roof of a building or at a location where people can hardly see it in order to avoid spoiling the external beauty of the building. Therefore, the conventional solar module 1 surely needs improving.

### SUMMARY OF THE INVENTION

The objective of this invention is to offer a variant packaging structure for a solar module. The solar module in the present invention is not a regular square in shape and has an outer side sealed with a packaging layer.

Apart from being able to convert solar energy into electric energy, the solar module of this invention can be made into various shapes for increasing decorative effect.

### BRIEF DESCRIPTION OF DRAWINGS

This invention will be better understood by referring to the accompanying drawings, wherein:

FIG. 1 is a perspective view of a conventional solar panel;

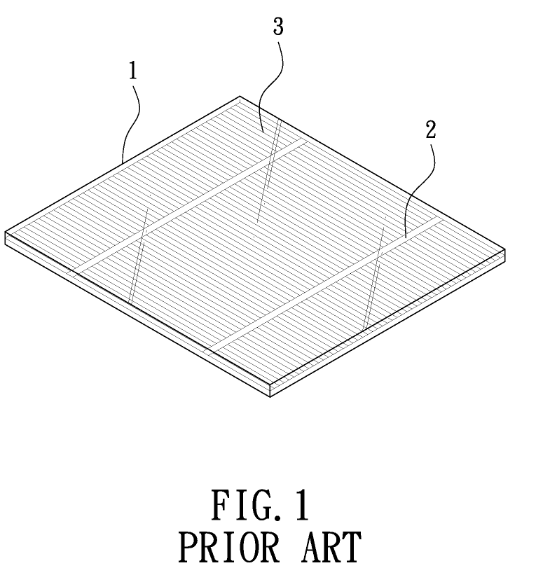

FIG. 2 is a perspective view of a first preferred embodiment of a variant packaging structure for a solar module in the present invention;

FIG. 3 is a perspective view of a second preferred embodiment of a variant packaging structure for a solar module in the present invention;

FIG. 4 is a perspective view of a third preferred embodiment of a variant packaging structure for a solar module in the present invention; and

FIG. 5 is a cross - sectional view of a fourth preferred embodiment of a variant packaging structure for a solar module in the present invention.

### DETAILED DESCRIPTION OF THE PREFERRED EMBODIMENT

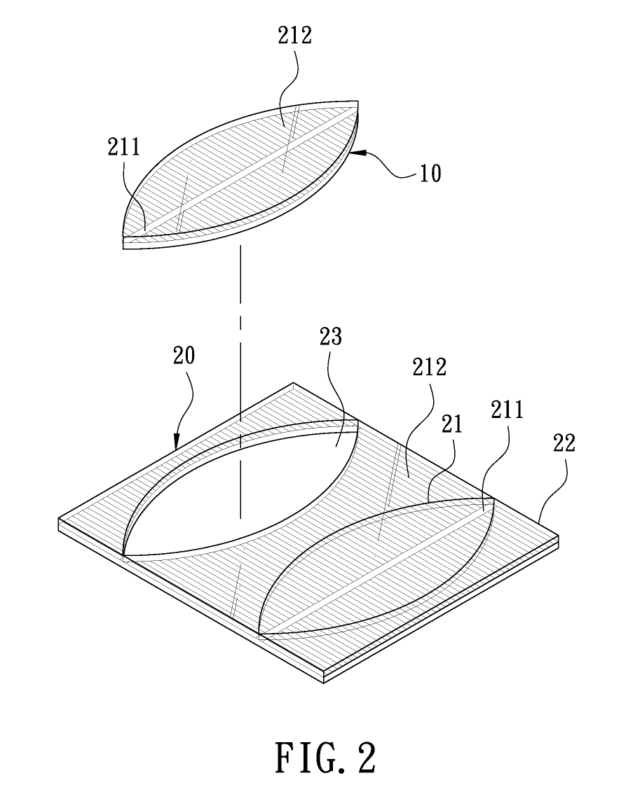

A first preferred embodiment of a variant packaging structure for a solar module in the present invention, as shown in FIG. 2, includes a solar module 10 shaped as an oval leaf and formed with a portion cut off a solar panel 20. The solar panel 20 has one side surface provided with a plurality of welded wires 21 respectively composed of plural main welded wires 211 and lots of connection welded wires 212. The main welded wires 211 spaced apart in parallel are disposed on the surface of the solar panel 20, while the connection welded wires 212 are formed at the opposite sides of the main welded wires 211, spaced apart and perpendicular to the main welded wires 211. Further, the solar panel 20 has an outer side sealed with a packaging layer 22 made of transparent epoxy resin. After being cut to make up the solar module 10 with the main welded wire 211 serving as a center line, the solar panel 20 will have a through hole 23 with a same shape as the solar module 10.

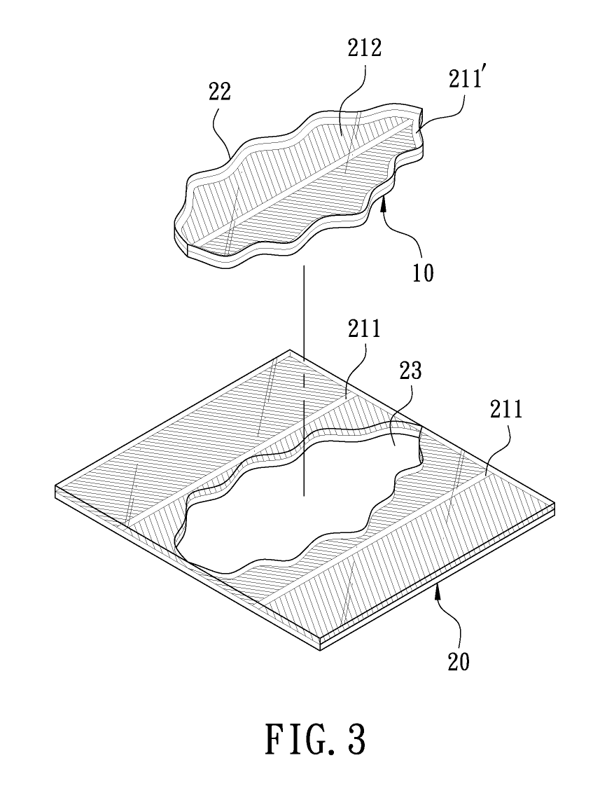

A second preferred embodiment of a variant packaging structure for a solar module in the present invention, as shown in FIG. 3, includes a solar module 10 that is a polygonal blade formed by cutting a central portion of a solar panel 20. The solar panel 20 has one side surface provided with three main welded wires 211 spaced apart and arranged in parallel, and two irregular-shaped sub-main welded wires 211′ are respectively disposed at the opposite sides of the intermediate one of the three main welded wires 211 to form the polygonal blade or the solar module 10. Further, all of the main welded wires 211 have opposite sides respectively disposed with lots of oblique, symmetrical and parallel connection welded wires 212. In this preferred embodiment, the main welded wires 211 and the connection welded wires 212 are formed by screen printing to imitate the dispersed condition of the veins of a real tree leaf. In addition, the solar panel 20 has an outer side sealed with a packaging layer 22, and after being cut to make up a solar module 10, the solar panel 20 will have a through hole 23 with a same shape matching with the solar module 10. Moreover, the shape of the through hole 23 of the solar panel 20 can serve as a contrast decoration, and the remainder of the solar panel 20 can be jointed together to make up porcelain tiles or solid decorations.

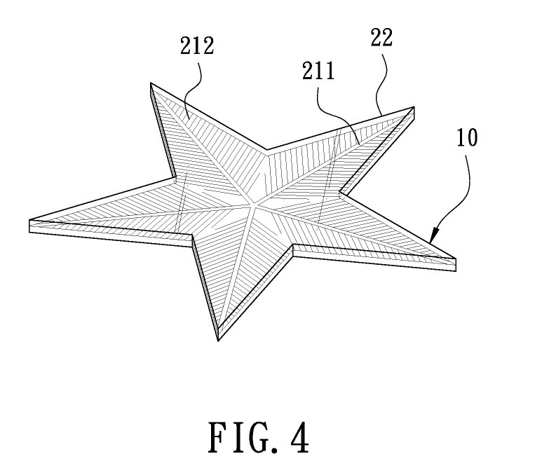

A third preferred embodiment of a variant packaging structure for a solar module in the present invention, as shown in FIG. 4, includes a solar module 10 cut into a polygonal body shaped as a star. The solar module 10 has one side surface provided with plural main welded wires 211 respectively extending from the center to each angle and having opposite sides respectively disposed with lots of connection welded wires 212 spaced apart and extending obliquely toward each end tip. In addition, the main welded wires 211 and the connection welded wires 212 are formed by screen printing.

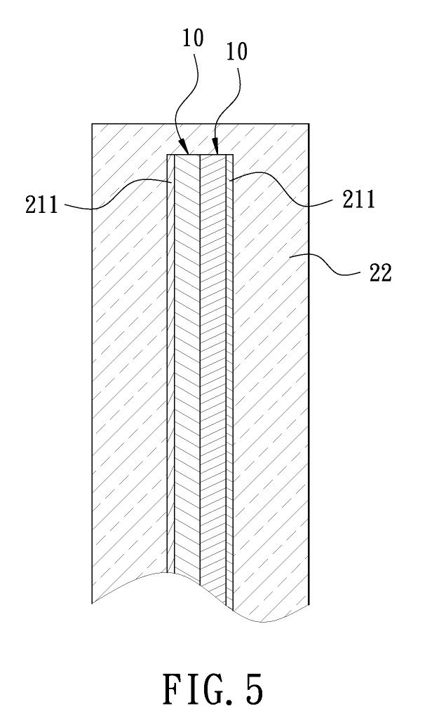

A fourth preferred embodiment of a variant packaging structure for a solar module in the present invention, as shown in FIG. 5, is constructed by having two solar modules 10 combined together reversely, letting the main welded wires 211 respectively located at the outer side of the solar module 10. The two solar modules 10 are integrally sealed together by means of a packaging layer 22.

While the preferred embodiments of the invention have been described above, it will be recognized and understood that various modifications may be made therein and the appended claims are intended to cover all such modifications that may fall within the spirit and scope of the invention.

I claim

1. A variant packaging structure for a solar module comprising at least one solar module, said solar module not shaped as a regular square, said solar module having an outer side sealed with a packaging layer.

2. The variant packaging structure for a solar module as claimed in claim 1, wherein said solar module has one side surface disposed with a plurality of welded wires.

3. The variant packaging structure for a solar module as claimed in claim 2, wherein said welded wires are respectively composed of plural main welded wires and plural connection welded wires, said main welded wires respectively distributed on a surface of said solar module, said connection welded wires spaced apart and arranged at opposite sides of said main welded wires.

4. The variant packaging structure for a solar module as claimed in claim 2, wherein said solar module is shaped as a leaf.

5. The variant packaging structure for a solar module as claimed in claim 2, wherein said solar module is polygonal in shape.

6. The variant packaging structure for a solar module as claimed in claim 2, wherein said solar module is formed a through hole.

7. The variant packaging structure for a solar module as claimed in claim 1, wherein said packaging layer is made of transparent epoxy resin.

8. The variant packaging structure for a solar module as claimed in claim 1, wherein said solar module is formed by reversely combining two solar modules together to let said main welded wires respectively located at an outer side of said solar module, said two solar modules having their outer sides sealed with said packaging layer.
